(19) United States
(12) Patent Application Publication
(10) Pub. No.: US 2026/0068764 A1
(43) Pub. Date: Mar. 5, 2026

(54) SEMICONDUCTOR DEVICE AND MANUFACTURING METHOD THEREOF

(71) Applicant: Innolux Corporation, Miaoli County (TW)

(72) Inventors: Jui-Jen Yueh, Miaoli County (TW); Cheng-Chi Wang, Miaoli County (TW)

(73) Assignee: Innolux Corporation, Miaoli County (TW)

(21) Appl. No.: 19/283,231

(22) Filed: Jul. 28, 2025

(30) Foreign Application Priority Data
Aug. 29, 2024 (CN) 202411202033.4

(51) Int. Cl. H01L 25/16; H01L 21/56; H01L 23/00; H01L 23/13; H01L 23/15; H01L 23/31; H01L 23/367; H01L 23/498

(52) U.S. Cl. CPC H01L 25/16

(57) ABSTRACT

A semiconductor device includes a circuit substrate, a first semiconductor element, a second semiconductor element, and a connection element. The circuit substrate includes a first pad. The first semiconductor element is disposed on the circuit substrate and includes a second pad and a third pad. The second semiconductor element is disposed on the circuit substrate. The connection element is disposed on the circuit substrate and electrically connects the first semiconductor element and the second semiconductor element. The connection element includes a fourth pad. The second pad is bonded to the first pad through a conductive material, and the third pad is directly bonded to the fourth pad.

### CROSS-REFERENCE TO RELATED APPLICATION

This application claims the priority benefit of China application serial no. 202411202033.4, filed on Aug. 29, 2024. The entirety of the above-mentioned patent application is hereby incorporated by reference herein and made a part of this specification.

### BACKGROUND

### Technical Field

The disclosure relates to a semiconductor device and a manufacturing method thereof, and in particular to a semiconductor device and a manufacturing method thereof having both the advantages of high performance and low cost.

### Description of Related Art

In the existing cross-chip signal connection technology, signals need to be transmitted through solder balls and long metal wires on a circuit board, so the required power consumption is very high. In order to solve the power consumption issue, the conventional semiconductor device implements signal exchange between multiple chips through a bridge element. The bridge element is disposed above the chips and is encapsulated by a packaging layer. That is, the chips are disposed between the bridge element and an organic packaging substrate, so the semiconductor device is prone to difficult heat dissipation. In addition, due to poor flatness of the organic packaging substrate, when bonding areas on two sides of the bridge element are bonded to the chips disposed on the organic packaging substrate, uneven stress may occur, thus causing the yield and the reliability of the semiconductor device to be poor.

### SUMMARY

The disclosure provides a semiconductor device and a manufacturing method thereof, which have both the advantages of high performance and low cost.

A semiconductor device of the disclosure includes a circuit substrate, a first semiconductor element, a second semiconductor element, and a connection element. The circuit substrate includes a first pad. The first semiconductor element is disposed on the circuit substrate and includes a second pad and a third pad. The second semiconductor element is disposed on the circuit substrate. The connection element is disposed on the circuit substrate and electrically connects the first semiconductor element and the second semiconductor element. The connection element includes a fourth pad. The second pad is bonded to the first pad through a conductive material, and the third pad is directly bonded to the fourth pad.

A manufacturing method of a semiconductor device of the disclosure includes the following steps. A circuit substrate is provided. The circuit substrate includes a first pad. A first semiconductor element is provided. The first semiconductor element includes a second pad and a third pad. A connection element is provided. The connection element includes a fourth pad. The third pad is directly bonded to the fourth pad. The first pad is bonded to the second pad through a conductive material.

A semiconductor device of the disclosure includes a first semiconductor element, a second semiconductor element, and a connection element. The connection element electrically connects the first semiconductor element and the second semiconductor element. The first semiconductor element includes a first pad and a first dielectric layer surrounding the first pad. The connection element includes a second pad and a second dielectric layer surrounding the second pad. The first pad is directly bonded to the second pad, and the first dielectric layer contacts the second dielectric layer. A material of one of the first dielectric layer and the second dielectric layer includes silicon oxide, and a material of other one of the first dielectric layer and the second dielectric layer includes silicon nitride.

Based on the above, in the embodiments of the disclosure, the second pad of the first semiconductor element is bonded to the first pad of the circuit substrate through the conductive material, and the third pad of the first semiconductor element is directly bonded to the fourth pad of the connection element, that is, general pads are bonded through the conductive material, and low-resistance high-density pads are bonded through hybrid bonding or metal-to-metal bonding. In this way, the semiconductor device of the disclosure can have both the advantages of high performance and low cost.

In order for the features and advantages of the disclosure to be more comprehensible, the following specific embodiments are described in detail in conjunction with the drawings.

### BRIEF DESCRIPTION OF THE DRAWINGS

FIG. 1A is a schematic top view of a semiconductor device according to an embodiment of the disclosure.

FIG. 1B is a schematic cross-sectional view along a line I-I of FIG. 1A.

FIG. 1C is a schematic cross-sectional view along a line II-II of FIG. 1A.

FIG. 1D is a schematic cross-sectional view along a line III-III of FIG. 1A.

FIG. 2A and FIG. 2B are schematic cross-sectional views before and after bonding a third pad of a first semiconductor element of the semiconductor device of FIG. 1A to a fourth pad of a connection element.

FIG. 2C and FIG. 2D are schematic cross-sectional views before and after bonding a third pad of a first semiconductor element to a fourth pad of a connection element according to another embodiment of the disclosure.

FIG. 3A is a schematic cross-sectional view of a fourth pad and a second dielectric layer of a connection element of the semiconductor device of FIG. 1A.

FIG. 3B is a schematic cross-sectional view of a fourth pad and a second dielectric layer of a connection element according to another embodiment of the disclosure.

FIG. 4A to FIG. 4G are schematic cross-sectional views of a manufacturing method of a semiconductor device according to an embodiment of the disclosure.

FIG. 5 is a schematic cross-sectional view of a semiconductor device according to an embodiment of the disclosure.

FIG. 6 is a schematic cross-sectional view of a semiconductor device according to another embodiment of the disclosure.

FIG. 7A is a schematic top view of a semiconductor device according to another embodiment of the disclosure.

FIG. 7B is a schematic cross-sectional view along a line IV-IV of FIG. 7A.

### DESCRIPTION OF THE EMBODIMENTS

The disclosure may be understood through referring to the following detailed description in conjunction with the drawings. It should be noted that in order to facilitate the understanding by the reader and the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as “containing” and “comprising” are open-ended words, which should be interpreted as “including but not limited to . . . ”.

In addition, relative terms such as “below” or “bottom portion” and “above” or “top portion” may be used in the embodiments to describe the relative relationship of one element to another element in the drawings. It should be understood that if a device in the drawings is turned upside down, elements described as “below” will become elements described as “above”.

In some embodiments of the disclosure, terms related to bonding and connection, such as “connection” and “interconnection”, unless otherwise defined, may refer to that two structures are directly in contact or may also refer to that two structures are not directly (indirectly) in contact, wherein there is another structure provided between the two structures. Also, the terms related to bonding and connection may also include the case where two structures are both movable or two structures are both fixed. Furthermore, the term “coupling” includes the transfer of energy between two structures through means of direct or indirect electrical connection or the transfer of energy between two separate structures by means of mutual induction.

It should be understood that when an element or a film layer is referred to as being “on” or “connected to” another element or film layer, the element may be directly on the other element or film layer or directly connected to the other element or film layer, or there is an intervening element or film layer between the two (indirect case). In contrast, when an element is referred to as being “directly on” or “directly connected to” another element or film layer, there is no intervening element or film layer between the two.

The terms “about”, “equal to”, “equivalent” or “same”, “substantially”, or “roughly” are generally interpreted as within 20% of a given value or range, or interpreted as within 10%, 5%, 3%, 2%, 1%, or 0.5% of the given value or range.

In the disclosure, the area, the width, the thickness, or the height of each element or the distance or the spacing between elements may be measured using an optical microscope (OM), a scanning electron microscope (SEM), a film thickness profiler (α-step), an ellipsometer, or other suitable manners. Specifically, according to some embodiments, a cross-sectional structural image including an element to be measured may be obtained using the scanning electron microscope, and the area, the width, the thickness, or the height of each element or the distance or the spacing between the elements is measured.

In the disclosure, the definition of roughness judgment may be observed by the SEM. On an uneven surface, it can be seen that there is a distance difference of 0.15 microns (μm) to 1 μm between peaks and valleys of surface undulations. The measurement of roughness judgment may include using the SEM, a transmission electron microscope (TEM), etc. to observe the surface undulations at the same appropriate magnification, and comparing the undulations by taking a sample of unit length (for example, 10 μm), which is a roughness range thereof. Here, “appropriate magnification” means that at least one surface may have a roughness (Rz) or an average roughness (Ra) of at least 10 undulating peaks visible under the field of view of such a magnification.

As used herein, the terms “film” and/or “layer” may refer to any continuous or discontinuous structure and material (for example, a material deposited by a method of the disclosure). For example, the film and/or the layer may include a two-dimensional material, a three-dimensional material, nanoparticles, or even a part of or a complete molecular layer, a part of or a complete atomic layer, or atomic and/or molecular clusters. The film or the layer may contain a material or a layer having pinholes, which may be at least partially continuous.

Although the terms first, second, third . . . may be used to describe various constituent elements, the constituent elements are not limited by the terms. The terms are only used to distinguish a single constituent element from other constituent elements in the specification. The same terms may not be used in the claims, but replaced by first, second, third . . . according to the order in which the elements are declared in the claims. Therefore, in the following specification, a first constituent element may be a second constituent element in the claims.

Unless otherwise defined, all terms (including technical and scientific terms) used herein have the same meaning as commonly understood by persons skilled in the art to which the disclosure belongs. It should be understood that the terms, such as the terms defined in commonly used dictionaries, should be interpreted as having meanings consistent with the prior art and the background or context of the disclosure, and should not be interpreted in an idealized or overly formal manner, unless specifically defined herein.

It should be noted that in the following embodiments, the technical features of several different embodiments may be replaced, reorganized, and mixed to complete other embodiments without departing from the spirit of the disclosure.

An electronic device of the disclosure may include a power module, a semiconductor device, a semiconductor packaging device, a display device, an antenna device, a sensing device, a light emitting device, or a splicing device, but not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a memristor, a filter, a diode, a transistor, a sensor, a microelectromechanical system (MEMS) element, and a liquid crystal chip, but not limited thereto. The diode may include a light emitting diode or a non-light emitting diode. The diode includes a P-N junction diode, a PIN diode, or a constant current diode. The light emitting diode may include, for example, an organic light emitting diode (OLED), a mini LED, a micro LED, a quantum dot LED, fluorescence, phosphor, other suitable materials, or a combination of the above, but not limited thereto. The sensor may include, for example, a capacitive sensor, an optical sensor, an electromagnetic sensor, a fingerprint sensor (FPS), a touch sensor, an antenna, a pen sensor, etc., but not limited thereto. The following description will take the display device as the electronic device to illustrate the disclosure, but the disclosure is not limited thereto. According to an embodiment of the disclosure, a manufacturing method of the electronic device provided may be applied, for example, to a wafer-level package (WLP) process or a panel-level package (PLP) process and may adopt a chip first process or a chip last/RDL first process, which will be further described in detail below. The electronic device referred to in the disclosure may include a system on integrated substrate (SoIS), a system in package (SiP), an antenna in package (AiP), or a combination of the above, but not limited thereto.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

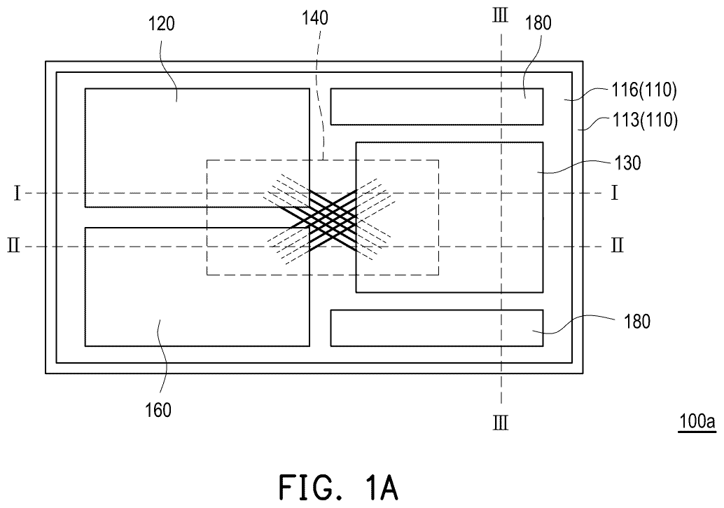

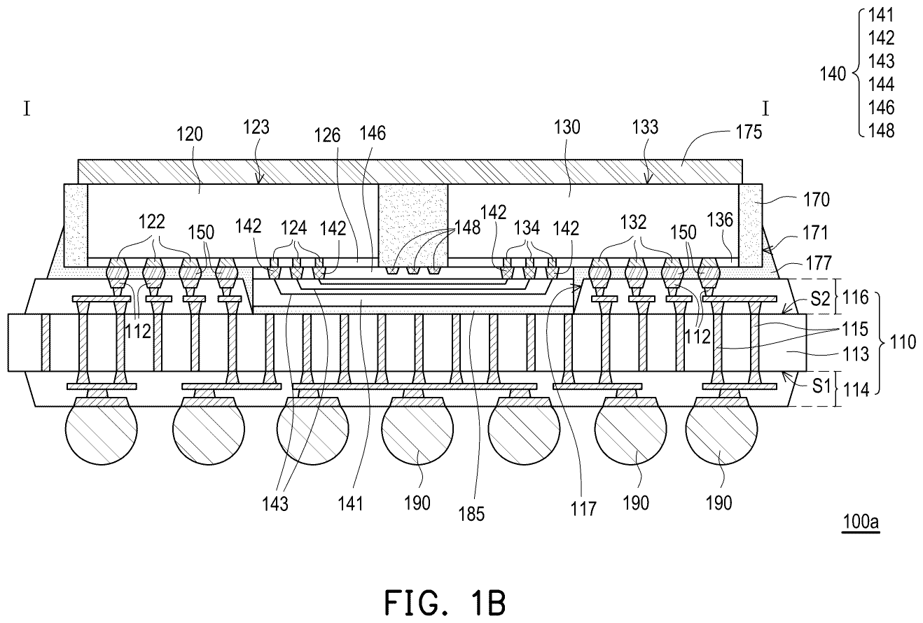

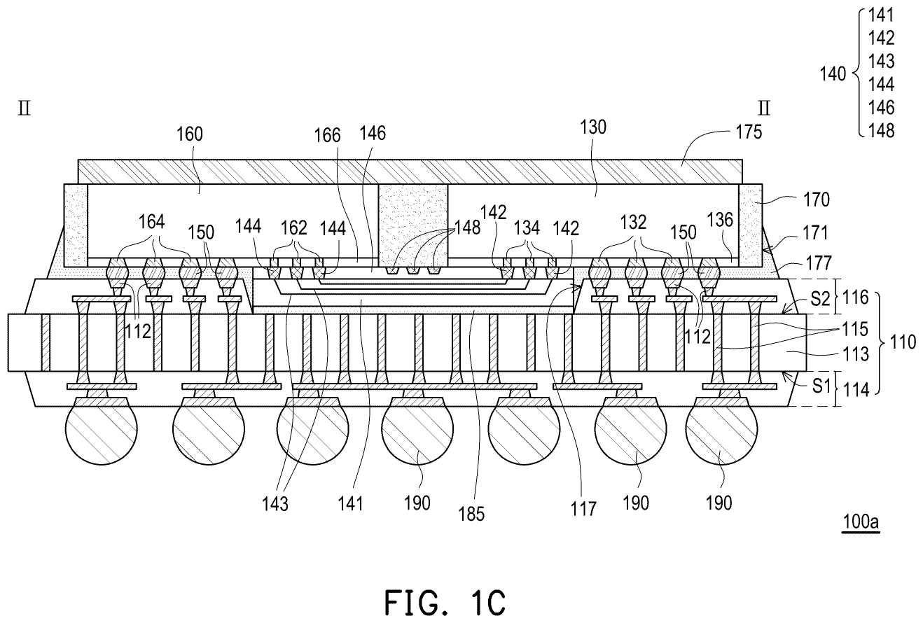

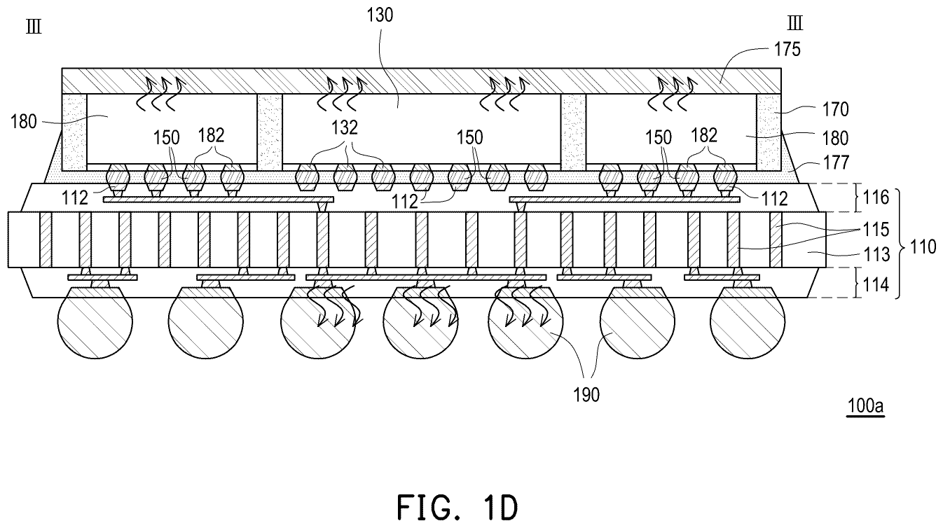

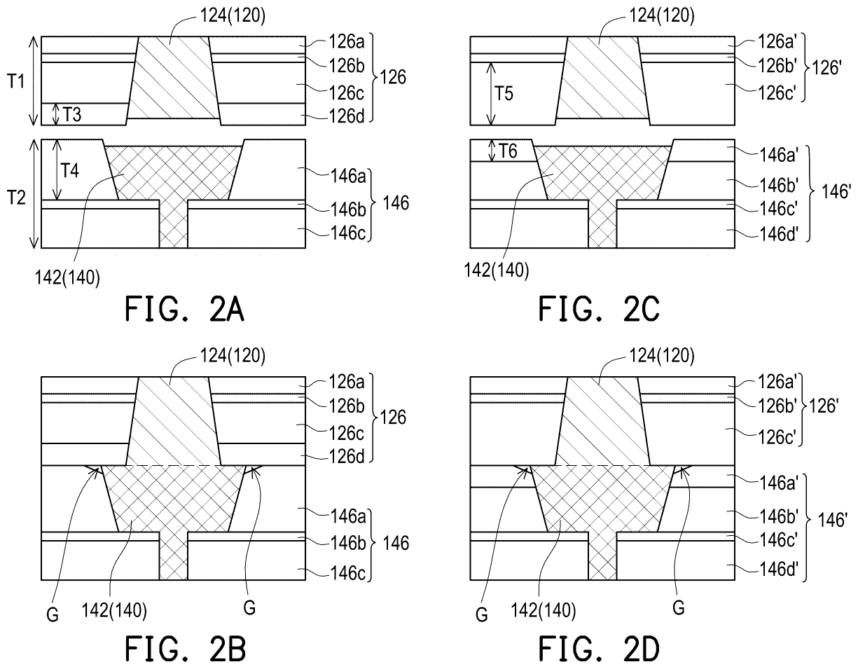

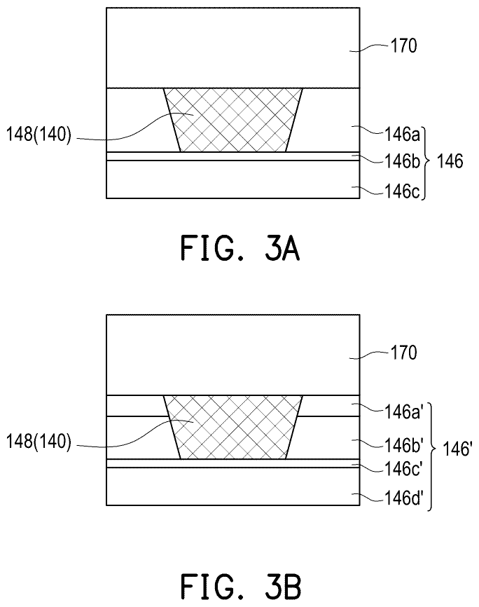

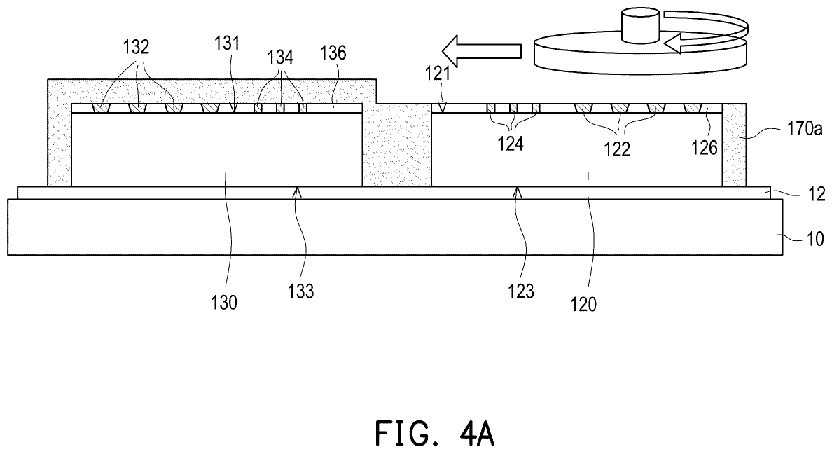

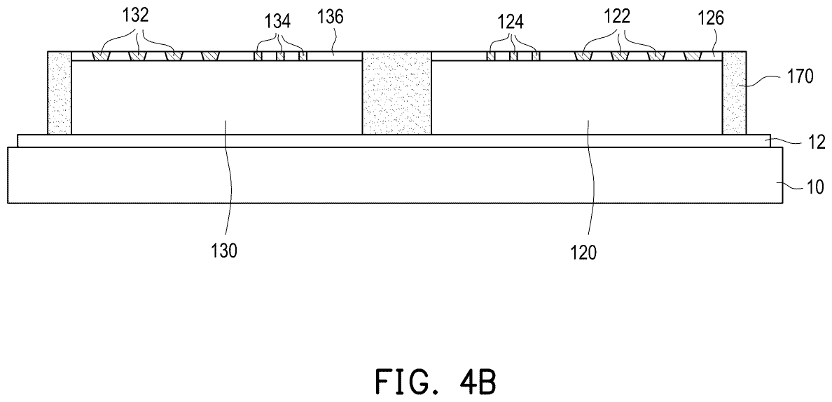

FIG. 1A is a schematic top view of a semiconductor device according to an embodiment of the disclosure. FIG. 1B is a schematic cross-sectional view along a line I-I of FIG. 1A. FIG. 1C is a schematic cross-sectional view along a line II-II of FIG. 1A. FIG. 1D is a schematic cross-sectional view along a line III-III of FIG. 1A. FIG. 2A and FIG. 2B are schematic cross-sectional views before and after bonding a third pad of a first semiconductor element of the semiconductor device of FIG. 1A to a fourth pad of a connection element. FIG. 2C and FIG. 2D are schematic cross-sectional views before and after bonding a third pad of a first semiconductor element to a fourth pad of a connection element according to another embodiment of the disclosure. FIG. 3A is a schematic cross-sectional view of a fourth pad and a second dielectric layer of a connection element of the semiconductor device of FIG. 1A. FIG. 3B is a schematic cross-sectional view of a fourth pad and a second dielectric layer of a connection element according to another embodiment of the disclosure. For convenience of explanation, some layers are omitted in FIG. 1A.

Please refer to FIG. 1A and FIG. 1B first. In the embodiment, a semiconductor device 100a includes a circuit substrate 110, a first semiconductor element 120, a second semiconductor element 130, and a connection element 140. The circuit substrate 110 includes a first pad 112. The first semiconductor element 120 is disposed on the circuit substrate 110 and includes a second pad 122 and a third pad 124. The second semiconductor element 130 is disposed on the circuit substrate 110. The connection element 140 is disposed on the circuit substrate 110 and electrically connects the first semiconductor element 120 and the second semiconductor element 130. The connection element 140 includes a fourth pad 142. The second pad 122 is bonded to the first pad 112 through a conductive material 150, and the third pad 124 is directly bonded to the fourth pad 142.

Specifically, in the embodiment, the circuit substrate 110 further includes a glass 113 and a first circuit 114 disposed on a first side S1 of the glass 113. The first pad 112 is disposed on a second side S2 of the glass 113, and the first pad 112 is electrically connected to the first circuit 114 through a via 115 in the glass 113. In an embodiment, the circuit substrate 110 is, for example, a through glass via (TGV) substrate, but not limited thereto. In an embodiment, the circuit substrate 110 further includes a second circuit 116 disposed on the second side S2 of the glass 113, and the first pad 112 is located on a side surface of the second circuit 116 away from the glass 113. The first circuit 114 and the second circuit 116 are electrically connected through the via 115. In an embodiment, the first circuit 114 and the second circuit 116 may be, for example, redistribution layers (RDL) that redistribute circuits and/or further increase circuit fan-out areas, but not limited thereto. In addition, as shown in FIG. 1B, the second circuit 116 of the embodiment has an opening 117, wherein the opening 117 exposes a part of the glass 113 and the via 115, and the first pad 112 is located around the opening 117, but not limited thereto. The semiconductor device 100a may further include an adhesion layer 185 disposed between the circuit substrate 110 and the connection element 140, wherein the connection element 140 is positioned in the opening 117 through the adhesion layer 185. In an embodiment, the material of the adhesion layer 185 may be, for example, acrylic glue, silicone glue, polyurethane glue, epoxy, optical clear adhesive (OCA), or optical clear resin (OCR), but not limited thereto.

Furthermore, the first semiconductor element 120 and the second semiconductor element 130 are separately disposed on the circuit substrate 110, wherein the connection element 140 is located between the first semiconductor element 120 and the second semiconductor element 130 and the circuit substrate 110. The second semiconductor element 130 includes a pad 132 and a pad 134. Here, the pad is embodied as a conductive contact. Here, the second pad 122 and the third pad 124 of the first semiconductor element 120 are located on the same side, and the pad 132 and the pad 134 of the second semiconductor element 130 are located on the same side. The second pad 122 of the first semiconductor element 120 and the pad 132 of the second semiconductor element 130 are disposed corresponding to the first pad 112 of the circuit substrate 110, wherein the second pad 122 and the pad 132 may be, for example, general pads. The second pad 122 and the pad 132 are respectively bonded to the first pad 112 through the conductive material 150, wherein the conductive material 150 may include, for example, tin, silver, bismuth, nickel, gold, other appropriate metals, or an alloy thereof, but not limited thereto. The third pad 124 of the first semiconductor element 120 and the pad 134 of the second semiconductor element 130 are disposed corresponding to the fourth pad 142 of the connection element 140, wherein the third pad 124 and the pad 134 may be, for example, low-impedance high-density pads. The third pad 124 and the pad 134 are respectively directly bonded to the fourth pad 142, wherein direct bonding means that there is no intervening layer between the two pads, and the two pads are bonded by, for example, metal-to-metal bonding such as copper-copper (Cu—Cu) bonding, to direct contact each other.

The second pad 122 of the first semiconductor element 120 of the embodiment is bonded to the first pad 112 of the circuit substrate 110 through the conductive material 150, and the third pad 124 of the first semiconductor element 120 is directly bonded to the fourth pad 142 of the connection element 140, that is, general pads are bonded through the conductive material 150, and low-resistance high-density pads are bonded through metal-to-metal bonding. Compared with a conventional semiconductor device that only adopts solder balls and long metal wires for transmission, in the embodiment, the third pad 124 of the first semiconductor element 120 is directly bonded to the fourth pad 142 of the connection element 140, which may effectively reduce the transmission path, thereby reducing power consumption. In addition, compared with the prior art in which the semiconductor device adopts a bridge element located above chips, the embodiment not only adopts the directly bonded pads, but also bonds the second pad 122 of the first semiconductor element 120 to the first pad 112 of the circuit substrate 110 through the conductive material 150, so the cost can be effectively reduced. In short, the semiconductor device 100a of the embodiment can have both the advantages of high performance and low cost.

Next, please refer to FIG. 1B, FIG. 2A, and FIG. 2B at the same time. In the embodiment, the first semiconductor element 120 further includes a first dielectric layer 126 surrounding the third pad 124, and the connection element 140 further includes a second dielectric layer 146 surrounding the fourth pad 142, wherein the first dielectric layer 126 contacts the second dielectric layer 146. Here, surrounding means completely surrounding or partially surrounding. Similarly, the second semiconductor element 130 further includes a dielectric layer 136 surrounding the pad 134, and the dielectric layer 136 contacts the second dielectric layer 146, wherein the dielectric layer 136 may have the same structure as the first dielectric layer 126, but not limited thereto. The material of the first dielectric layer 126 may be different from the material of the second dielectric layer 146. In an embodiment, the material of one of the first dielectric layer 126 and the second dielectric layer 146 includes silicon oxide, and the material of the other one of the first dielectric layer 126 and the second dielectric layer 146 includes silicon nitride.

Specifically, in the embodiment, the first dielectric layer 126 includes a dielectric layer 126a, a dielectric layer 126b, a dielectric layer 126c, and a dielectric layer 126d, wherein the materials of the dielectric layer 126a and the dielectric layer 126c are silicon oxide, and the materials of the dielectric layer 126b and the dielectric layer 126d are silicon nitride, but not limited thereto. In an embodiment, the thicknesses of the dielectric layer 126a, the dielectric layer 126b, the dielectric layer 126c, and the dielectric layer 126d are different, but not limited thereto. The second dielectric layer 146 includes a dielectric layer 146a, a dielectric layer 146b, and a dielectric layer 146c, wherein the materials of the dielectric layer 146a and the dielectric layer 146c are silicon oxide, and the materials of the dielectric layer 146b is silicon nitride, but not limited thereto. In an embodiment, the thicknesses of the dielectric layer 146a, the dielectric layer 146b, and the dielectric layer 146c are different, but not limited thereto. The thickness of one of the first dielectric layer 126 and the second dielectric layer 146 is greater than the thickness of the other one of the first dielectric layer 126 and the second dielectric layer 146. In an embodiment, a thickness T1 of the first dielectric layer 126 is less than a thickness T2 of the second dielectric layer 146, but not limited thereto. It should be noted that the thickness comparison between the two uses the thicknesses on the same measurement line, and the measurement line is parallel to the normal direction of the circuit substrate 110, but not limited thereto.

Please refer to FIG. 2A. Before bonding, the surface of the third pad 124 is slightly lower than the surface of the dielectric layer 126d, and the surface of the fourth pad 142 is slightly lower than the surface of the dielectric layer 146a. Next, please refer to FIG. 2B. The dielectric layer 126d and the dielectric layer 146a of different thicknesses are directly connected using van der Waals force through a low-temperature procedure, and the third pad 124 is aligned with the fourth pad 142. Afterwards, through a high-temperature procedure, the third pad 124 and the fourth pad 142 are directly bonded together due to thermal expansion, and the dielectric layer 126d and the dielectric layer 146a are directly bonded together. Here, the bonding (that is, metal-to-metal bonding) of the third pad 124 and the fourth pad 142 and the bonding of the dielectric layer 126d and the dielectric layer 146a may be referred to as hybrid bonding. Since the bonded dielectric layer 126d and dielectric layer 146a are made of different materials and have different thicknesses, wherein the dielectric layer 126d (whose material is silicon nitride) may be adjusted for tensile stress, the dielectric layer 146a (whose material is silicon oxide) may be adjusted for compressive stress, and a thickness T4 of the dielectric layer 146a is greater than a thickness T3 of the dielectric layer 126d, stress can be effectively balanced. In an embodiment, the semiconductor device 100a may further include a gap G disposed between a part of the first dielectric layer 126 and a part of the second dielectric layer 146, and the gap G is adjacent to the third pad 124 or the fourth pad 142. In an embodiment, there are no gaps between the dielectric layers in the first dielectric layer 126, and there are no gaps between the dielectric layers in the second dielectric layer 146.

In another embodiment, please refer to FIG. 2C and FIG. 2D at the same time. A first dielectric layer 126′ includes a dielectric layer 126a′, a dielectric layer 126b′, and a dielectric layer 126c′, wherein the materials of the dielectric layer 126a′ and the dielectric layer 126c′ are silicon oxide, and the material of the dielectric layer 126b′ is silicon nitride, but not limited thereto. In an embodiment, the thicknesses of the dielectric layer 126a′, the dielectric layer 126b′, and the dielectric layer 126c′ are different, but not limited thereto. A second dielectric layer 146′ includes a dielectric layer 146a′, a dielectric layer 146b′, a dielectric layer 146c′, and a dielectric layer 146d′, wherein the materials of the dielectric layer 146a′ and the dielectric layer 146c′ are silicon nitride, and the materials of the dielectric layer 146b′ and the dielectric layer 146d′ are silicon oxide, but are not limited thereto. In an embodiment, the thicknesses of the dielectric layer 146a′, the dielectric layer 146b′, the dielectric layer 146c′, and the dielectric layer 146d′ are different, but not limited thereto. During bonding, since the bonded dielectric layer 126c′ and dielectric layer 146a′ are made of different materials and have different thicknesses, wherein the dielectric layer 126c′ (whose material is silicon oxide) may be adjusted for compressive stress, the dielectric layer 146a′ (whose material is silicon nitride) may be adjusted for tensile stress, and a thickness T5 of the dielectric layer 126c′ is greater than a thickness T6 of the dielectric layer 146a′, stress can be effectively balanced.

Furthermore, please refer to FIG. 1A and FIG. 1C at the same time. In the embodiment, the semiconductor device 100a may further include a third semiconductor element 160 disposed on the circuit substrate 110, wherein the third semiconductor element 160 includes a fifth pad 162, a pad 164, and a dielectric layer 166 surrounding the fifth pad 162 and the pad 164, and the connection element 140 further includes a sixth pad 144. The pad 164 is bonded to the first pad 112 through the conductive material 150, the fifth pad 162 is directly bonded to the sixth pad 144, and the dielectric layer 166 directly contacts the second dielectric layer 146. In an embodiment, the dielectric layer 166 may have the same structure as the dielectric layer 136, but not limited thereto. In an embodiment, the first semiconductor element 120, the second semiconductor element 130, and the third semiconductor element 160 may respectively be, for example, a system on chip, a dynamic random access memory, a cache, a high bandwidth memory (HBM), a photonic integrated circuit, an application-specific integrated circuit, or other logical integrated circuits, but not limited thereto. In an embodiment, the connection element 140 may further include a silicon substrate 141 and a circuit layer 143 formed in or on the silicon substrate 141.

Please refer to FIG. 1B and FIG. 1C at the same time. In order to maintain or protect the electrical performance between the first pad 112 and the second pad 122, the electrical performance between the first pad 112 and the pad 132, and the electrical performance between the first pad 112 and the pad 164, the semiconductor device 100a of the embodiment further includes an underfill 177 disposed between the first semiconductor element 120 and the circuit substrate 110, between the second semiconductor element 130 and the circuit substrate 110, and between the third semiconductor element 160 and the circuit substrate 110, wherein the underfill 177 encapsulates the conductive material 150. In an embodiment, the underfill 177 may extend to cover a surrounding surface 171 of a packaging layer 170 and the opening 117 of the second circuit 116.

Please refer to FIG. 1B and FIG. 3A at the same time. In the embodiment, the semiconductor device 100a further includes the packaging layer 170 disposed adjacent to the first semiconductor element 120 and the second semiconductor element 130, wherein the connection element 140 further includes a dummy pad 148 contacting the packaging layer 170. As shown in FIG. 3A, the packaging layer 170 directly contacts the dummy pad 148 and the dielectric layer 146a (whose material is silicon oxide), wherein there is no electrical connection between the dummy pad 148 and the circuit layer 143 and the fourth pad 142 of the connection element 140. The purpose of setting the dummy pad 148 is to balance stress during bonding. In an embodiment, the material of the packaging layer 170 may include an inorganic material such as silicon oxide or silicon nitride, but not limited thereto. In another embodiment, as shown in FIG. 3B, the packaging layer 170 may also directly contact the dummy pad 148 and the dielectric layer 146a′ (whose material is silicon nitride).

Please refer to FIG. 1B again. In the embodiment, the semiconductor device 100a further includes a heat dissipation layer 175 disposed on the first semiconductor element 120 and the second semiconductor element 130. In an embodiment, the material of the heat dissipation layer 175 may be, for example, metal, silicon, silicon carbide, graphite, graphene, or other suitable materials, but not limited thereto. Please refer to FIG. 1A and FIG. 1D again. In order to increase heat dissipation or stress balance, in an embodiment, the semiconductor device 100a may further include a dummy semiconductor element 180 disposed adjacent to the first semiconductor element 120 and the second semiconductor element 130 or adjacent to the second semiconductor element 130 and the third semiconductor element 160, and the dummy semiconductor element 180 does not overlap with the connection element 140. Here, the dummy semiconductor element 180 does not process or compute data, but is only used for stress balancing or heat dissipation. In addition, the semiconductor device 100a of the embodiment further includes a solder ball 190 disposed on a side of the circuit substrate 110 relatively away from the first semiconductor element 120 and the second semiconductor element 130, and electrically connected to the first circuit 114, so that the semiconductor device 100a is electrically connected to an external circuit. In an embodiment, heat generated by the first semiconductor element 120 and the second semiconductor element 130 may not only be conducted through the heat dissipation layer 175 in direct contact, but may also be conducted to the solder ball 190 to be transferred to the outside through the second circuit 116, the via 115, and the first circuit 114.

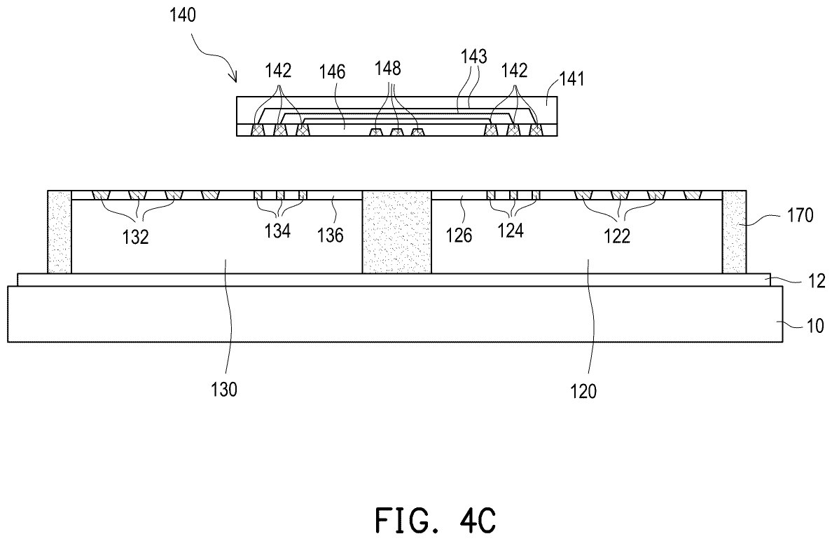

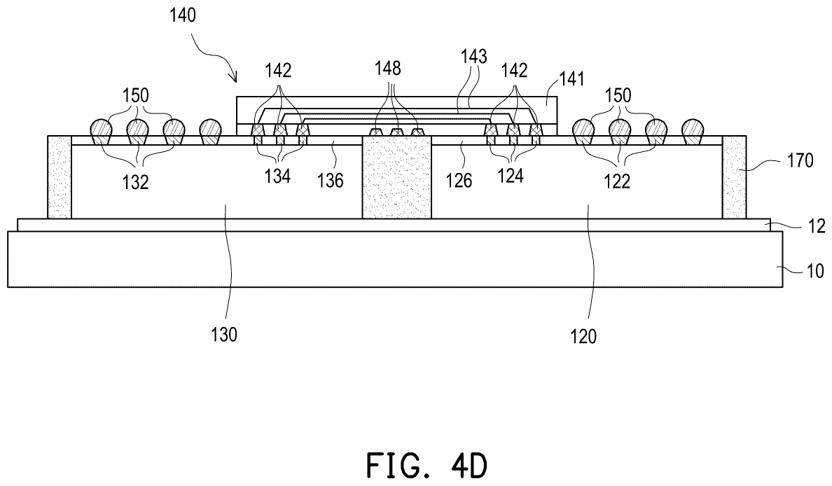

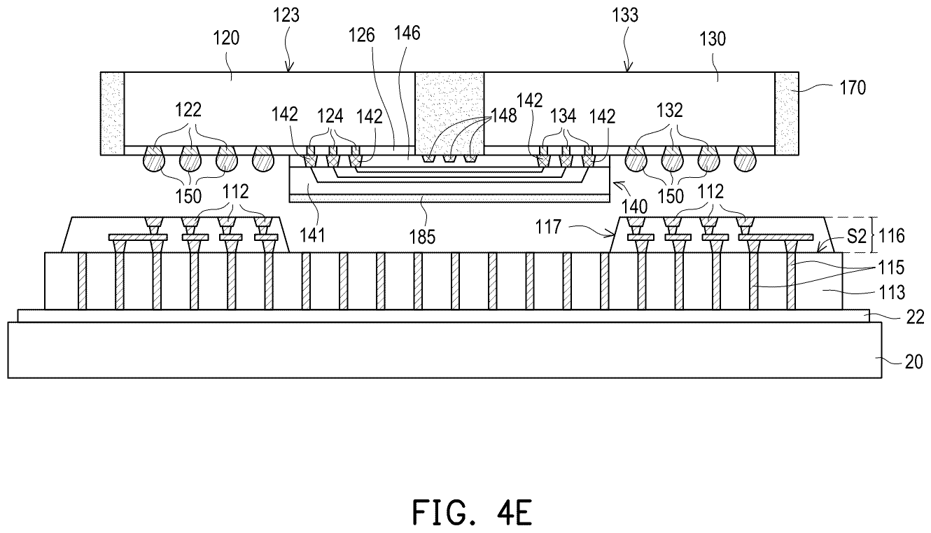

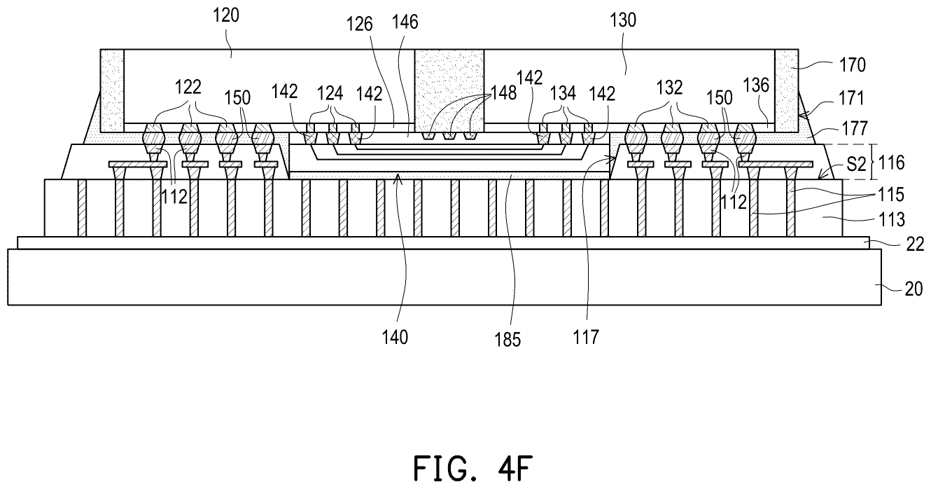

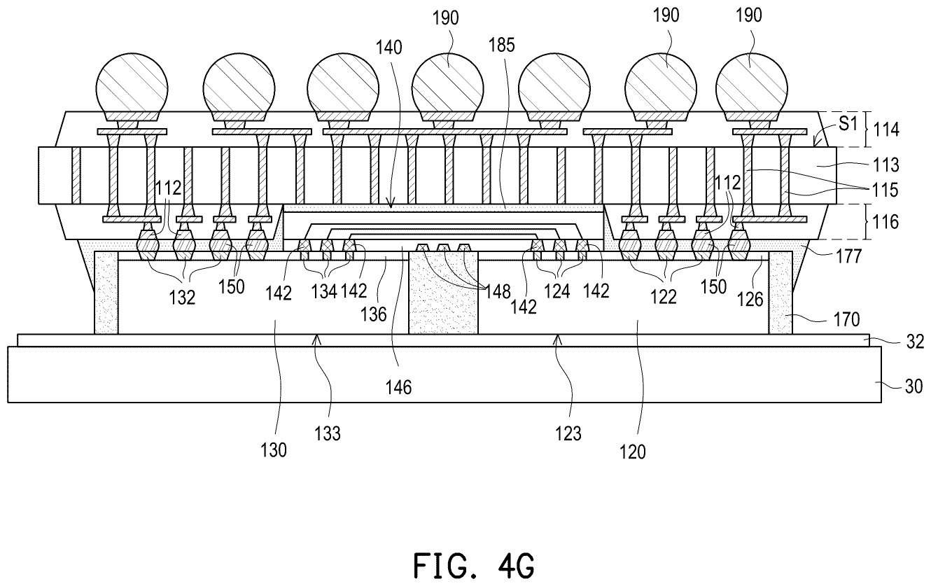

In terms of manufacturing process, FIG. 4A to FIG. 4G are schematic cross-sectional views of a manufacturing method of a semiconductor device according to an embodiment of the disclosure. Please refer to FIG. 4A first. Regarding the manufacturing method of the semiconductor device of the embodiment, first, a carrier 10 and an adhesion layer 12 thereon are provided. In an embodiment, the carrier 10 may be, for example, a glass substrate, a printed circuit board, a fiberglass (FR4) substrate, a steel (steel) substrate, or other suitable substrates, but not limited thereto. Next, the first semiconductor element 120 and the second semiconductor element 130 are disposed on the carrier 10, wherein the first semiconductor element 120 uses a back surface 123 and the second semiconductor element 130 uses a back surface 133 to directly contact the adhesion layer 12 on the carrier 10, so as to positioned on the carrier 10. The first semiconductor element 120 includes the second pad 122 and the third pad 124 located on an active surface 121 and the first dielectric layer 126 surrounding the second pad 122 and the third pad 124. The second semiconductor element 130 includes the pad 132 and the pad 134 located on an active surface 131 and the dielectric layer 136 surrounding the pad 132 and the pad 134. Next, a packaging procedure is performed to cover the first semiconductor element 120 and the second semiconductor element 130 with a packaging layer 170a. In an embodiment, the material of the packaging layer 170a includes an inorganic material such as silicon oxide and silicon nitride, but not limited thereto.

Next, please refer to FIG. 4A and FIG. 4B at the same time. A mechanical polishing procedure or a chemical mechanical polishing (CMP) procedure is, for example, performed to remove a part of the packaging layer 170a to expose the second pad 122 and the third pad 124 of the first semiconductor element 120 and the pad 132 and the pad 134 of the semiconductor element 130 to form the packaging layer 170.

Next, please refer to FIG. 4C. The connection element 140 is provided, wherein the connection element 140 includes the fourth pad 142 and the second dielectric layer 146 surrounding the fourth pad 142. In an embodiment, the connection element 140 may further include the silicon substrate 141 and the circuit layer 143 formed in or on the silicon substrate 141. The connection element 140 may further include the dummy pad 148, wherein the second dielectric layer 146 surrounds the dummy pad 148, and there is no electrical connection between the dummy pad 148 and the circuit layer 143 and the fourth pad 142 of the connection element 140. The purpose of setting the dummy pad 148 is to balance stress during bonding.

Next, please refer to FIG. 4D. The third pad 124 and the fourth pad 142 are directly bonded and the pad 134 and the fourth pad 142 are directly bonded. Here, direct bonding means that there is no intervening layer between the two pads, and the two pads are bonded by, for example, metal-to-metal bonding such as copper-copper (Cu—Cu) bonding, to direct contact each other. At this time, the dummy pad 148 directly contacts the packaging layer 170. Next, the conductive material 150 is formed on the second pad 122 of the first semiconductor element 120 and the pad 132 of the second semiconductor element 130.

Please refer to FIG. 4D and FIG. 4E at the same time. A carrier 20 and an adhesion layer 22 thereon, the glass 113, and the second circuit 116 disposed on the second side S2 of the glass 113 are provided. The glass 113 is positioned on the carrier 20 through the adhesion layer 22 on the carrier 20, wherein the first pad 112 is disposed on the second side S2 of the glass 113, and the first pad 112 is electrically connected to the via 115 in the glass 113 through the second circuit 116. The second circuit 116 of the embodiment has the opening 117, wherein the opening 117 exposes a part of the glass 113 and the via 115, and the first pad 112 is located around the opening 117, but not limited thereto. Next, the structure of FIG. 4D is flipped, and the carrier 10 and the adhesion layer 12 thereon are removed to expose the back surface 123 of the first semiconductor element 120 and the back surface 133 of the second semiconductor element 130, and form the adhesion layer 185 on the silicon substrate 141 of the connection element 140. In another embodiment, the adhesion layer 185 is formed on the part of the glass 113 exposed by the opening 117. In an embodiment, the material of the adhesion layer 185 may be, for example, optical clear adhesive (OCA) or optical clear resin (OCR), but not limited thereto.

Next, please refer to FIG. 4F. The first pad 112 of the circuit substrate 110 and the second pad 122 of the first semiconductor element 120 are bonded through the conductive material 150, and the first pad 112 of the circuit substrate 110 and the pad 132 of the second semiconductor element 130 are bonded. In other words, the step of directly bonding the third pad 124 and the fourth pad 142 is before the step of bonding the first pad 112 and the second pad 122 through the conductive material 150. At this time, the adhesion layer 185 is located between the circuit substrate 110 and the connection element 140, wherein the connection element 140 is positioned in the opening 117 through the adhesion layer 185. In order to maintain or protect the electrical performance between the first pad 112 and the second pad 122 and the electrical performance between the first pad 112 and the pad 132, the underfill 177 may be formed between the first semiconductor element 120 and the circuit substrate 110 and between the second semiconductor element 130 and the circuit substrate 110. In an embodiment, the underfill 177 may extend to cover the surrounding surface 171 of the packaging layer 170 and the opening 117 of the second circuit 116.

After that, please refer to FIG. 4F and FIG. 4G. A carrier 30 and an adhesion layer 32 thereon are provided, the structure of FIG. 4F is flipped, and the back surface 123 of the first semiconductor element 120 and the back surface 133 of the second semiconductor element 130 directly contact the adhesion layer 32 to be positioned on the carrier 30 through the adhesion layer 32. Next, the carrier 20 and the adhesion layer 22 thereon are removed to expose the glass 113 and the via 115. Next, the first circuit 114 is formed on the first side S1 of the glass 113. So far, the circuit substrate 110 including the first pad 112 is provided. In an embodiment, the circuit substrate is, for example, a through glass via (TGV) substrate, but not limited thereto.

Next, please refer to FIG. 4G again. The solder ball 190 is formed on the side of the circuit substrate 110 relatively away from the first semiconductor element 120 and the second semiconductor element 130, wherein the solder ball 190 is electrically connected to the first circuit 114 for electrical connection with the external circuit.

Finally, please refer to FIG. 4G and FIG. 1B at the same time. The structure of FIG. 4G is flipped, and the carrier 30 and the adhesion layer 32 thereon are removed to expose the back surface 123 of the first semiconductor element 120 and the back surface 133 of the second semiconductor element 130. Afterwards, the heat dissipation layer 175 is formed on the back surface 123 of the first semiconductor element 120 and the back surface 133 of the second semiconductor element 130, wherein the heat dissipation layer 175 directly contacts the first semiconductor element 120, the second semiconductor element 130, and the packaging layer 170 to dissipate heat from the first semiconductor element 120 and the second semiconductor element 130. In an embodiment, the material of the heat dissipation layer 175 may be, for example, metal, silicon, silicon carbide, graphite, graphene, or other suitable materials, but not limited thereto. So far, the manufacturing of the semiconductor device 100a is completed.

It should be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

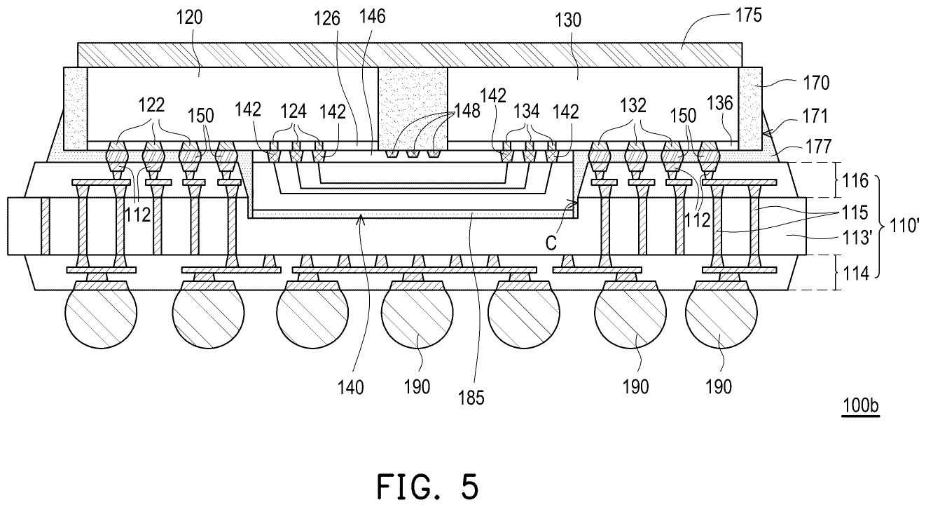

FIG. 5 is a schematic cross-sectional view of a semiconductor device according to another embodiment of the disclosure. Please refer to FIG. 1B and FIG. 5 at the same time first. The semiconductor device 100b of the embodiment is similar to the semiconductor device 100a of FIG. 1B. The difference between the two is that in the embodiment, a glass 113′ of a circuit substrate 110′ includes a groove C for accommodating the connection element 140. Here, the groove C does not penetrate the glass 113′. Since the embodiment has the design of the groove C, the selection of the size (including the thickness or the height) of the connection element 140 is more flexible.

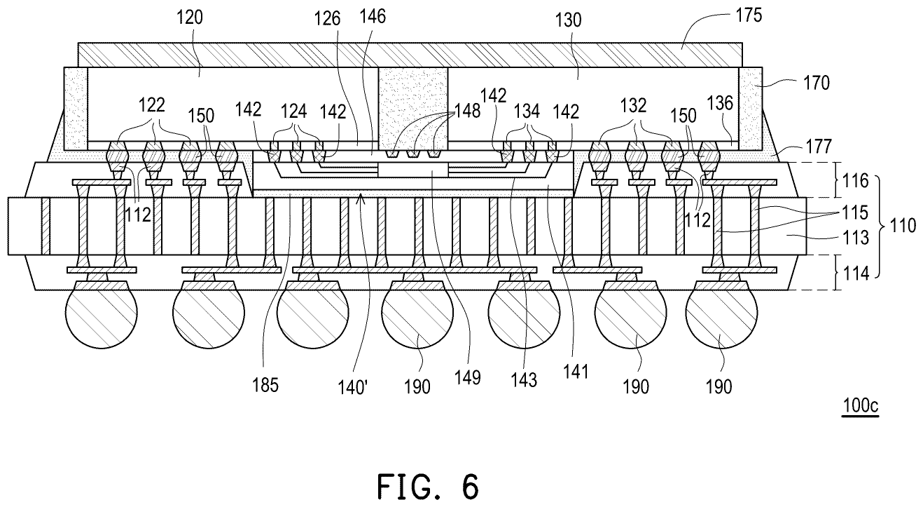

FIG. 6 is a schematic cross-sectional view of a semiconductor device according to another embodiment of the disclosure. Please refer to FIG. 1B and FIG. 6 at the same time first. A semiconductor device 100c of the embodiment is similar to the semiconductor device 100a of FIG. 1B. The difference between the two is that in the embodiment, a connection element 140′ further includes an active element 149, wherein the active element 149 may be disposed in the silicon substrate 141 and electrically connected to the circuit layer 143. In an embodiment, the active element 149 may be, for example, a thin film transistor or a complementary metal oxide semiconductor (CMOS) element, but not limited thereto.

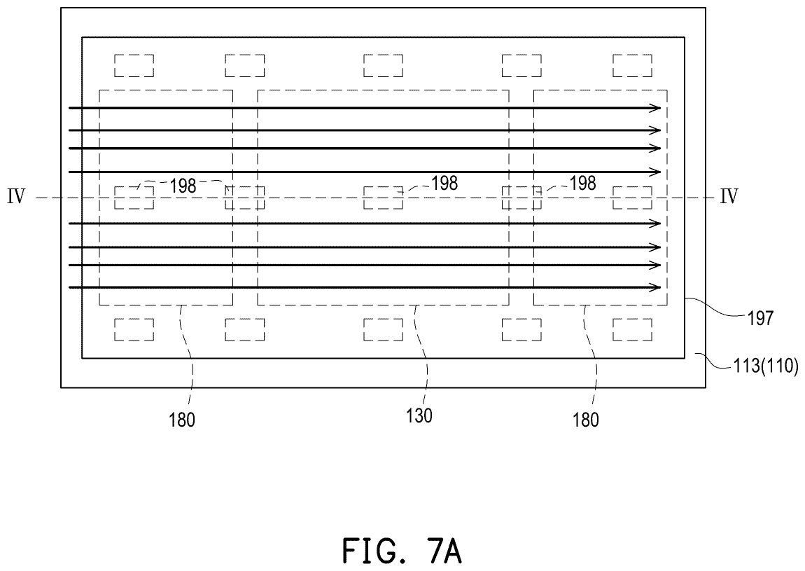

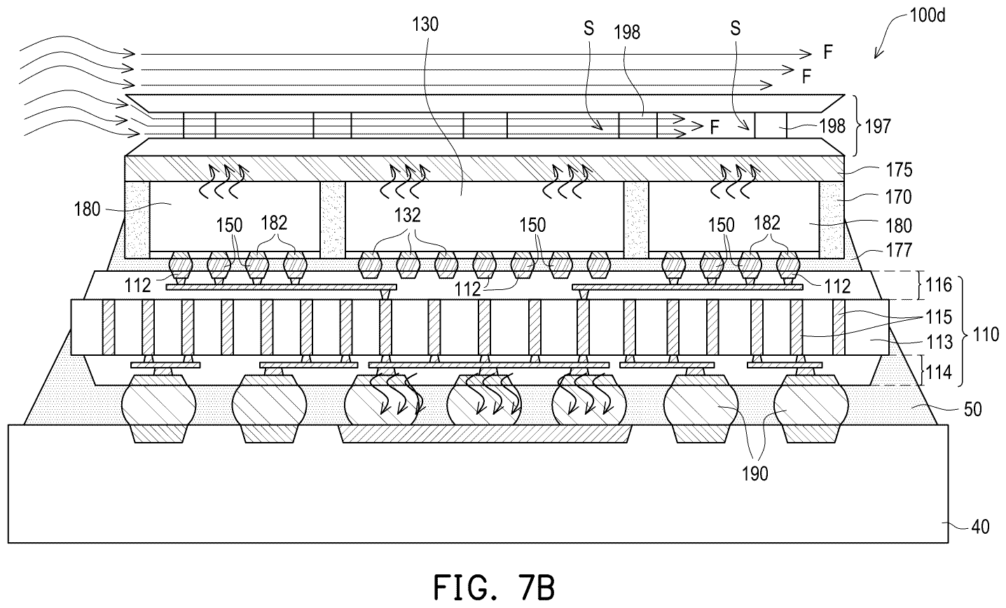

FIG. 7A is a schematic top view of a semiconductor device according to another embodiment of the disclosure. FIG. 7B is a schematic cross-sectional view along a line IV-IV of FIG. 7A. Please refer to FIG. 1C, FIG. 7A, and FIG. 7B at the same time first. A semiconductor device 100d of the embodiment is similar to the semiconductor device 100a of FIG. 1C. The difference between the two is that in the embodiment, the semiconductor device 100d further includes a heat dissipation auxiliary unit 197 disposed on the heat dissipation layer 175 and including multiple pillars 198 to define multiple cavities S. A fluid F may be, for example, a liquid or a gas flowing through the heat dissipation auxiliary unit 197, and the setting of the pillars 198 may allow the fluid F to stay briefly in the cavities S to reduce the flow rate, so that the fluid F may take away more heat, which can increase the heat dissipation effect of the semiconductor device 100d. In an embodiment, the material of the heat dissipation auxiliary unit 197 includes metal, silicon, or a high thermal conductivity material, but not limited thereto. Furthermore, the semiconductor device 100d of the embodiment is electrically connected to a carrier 40 through the solder ball 190, wherein the carrier 40 may be, for example, a printed circuit board (PCB) or a universal baseboard (UBB), but not limited thereto. In addition, in order to maintain/protect the electrical relationship between the solder ball 190 and the carrier 40, the solder ball 190 may also be encapsulated through an underfill 50, wherein the underfill 50 may also extend to cover the surrounding surface of the circuit substrate 110, but not limited thereto.

In summary, in the embodiments of the disclosure, the second pad of the first semiconductor element is bonded to the first pad of the circuit substrate through the conductive material, and the third pad of the first semiconductor element is directly bonded to the fourth pad of the connection element, that is, general pads are bonded through the conductive material, and low-resistance high-density pads are bonded through metal-to-metal bonding. In this way, the semiconductor device of the disclosure can have both the advantages of high performance and low cost.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor device, comprising:
a circuit substrate, comprising a first pad;
a first semiconductor element, disposed on the circuit substrate and comprising a second pad and a third pad;
a second semiconductor element, disposed on the circuit substrate; and
a connection element, disposed on the circuit substrate and electrically connecting the first semiconductor element and the second semiconductor element, the connection element comprising a fourth pad,
wherein the second pad is bonded to the first pad through a conductive material, and the third pad is directly bonded to the fourth pad.

2. The semiconductor device according to claim 1, wherein the circuit substrate further comprises a glass and a first circuit disposed on a first side of the glass, the first pad is disposed on a second side of the glass, and the first pad is electrically connected to the first circuit through a via in the glass.

3. The semiconductor device according to claim 2, wherein the glass comprises a groove for accommodating the connection element.

4. The semiconductor device according to claim 1, further comprising:
a third semiconductor element, disposed on the circuit substrate, wherein the third semiconductor element comprises a fifth pad, the connection element further comprises a sixth pad, and the fifth pad is directly bonded to the sixth pad.

5. The semiconductor device according to claim 1, wherein the first semiconductor element further comprises a first dielectric layer surrounding the third pad, the connection element further comprises a second dielectric layer surrounding the fourth pad, and the first dielectric layer contacts the second dielectric layer.

6. The semiconductor device according to claim 5, wherein a material of the first dielectric layer is different from a material of the second dielectric layer.

7. The semiconductor device according to claim 6, wherein a material of one of the first dielectric layer and the second dielectric layer comprises silicon oxide, and a material of other one of the first dielectric layer and the second dielectric layers comprises silicon nitride.

8. The semiconductor device according to claim 7, wherein a thickness of one of the first dielectric layer and the second dielectric layer is greater than a thickness of other one of the first dielectric layer and the second dielectric layer.

9. The semiconductor device according to claim 1, further comprising:
a packaging layer, disposed adjacent to the first semiconductor element and the second semiconductor element, wherein the connection element further comprises a dummy pad contacting the packaging layer.

10. The semiconductor device according to claim 1, further comprising:
a heat dissipation layer, disposed on the first semiconductor element and the second semiconductor element.

11. The semiconductor device according to claim 1, wherein the connection element comprises an active element.

12. The semiconductor device according to claim 1, further comprising:
a dummy semiconductor element, disposed adjacent to the first semiconductor element and the second semiconductor element, wherein the dummy semiconductor element does not overlap with the connection element.

13. The semiconductor device according to claim 1, further comprising:
an adhesive layer, disposed between the circuit substrate and the connection element.

14. A manufacturing method of a semiconductor device, comprising:
providing a circuit substrate, wherein the circuit substrate comprises a first pad;
providing a first semiconductor element, wherein the first semiconductor element comprises a second pad and a third pad;
providing a connection element, wherein the connection element comprises a fourth pad;
directly bonding the third pad to the fourth pad; and
bonding the first pad to the second pad through a conductive material.

15. The manufacturing method of the semiconductor device according to claim 14, wherein the step of directly bonding the third pad to the fourth pad is before the step of bonding the first pad to the second pad through the conductive material.

16. The manufacturing method of the semiconductor device according to claim 14, further comprising:
providing a carrier;
disposing the first semiconductor element on the carrier;
forming a packaging layer on the carrier to cover the first semiconductor element; and
removing a part of the packaging layer to expose the second pad and the third pad.

17. A semiconductor device, comprising:
a first semiconductor element;
a second semiconductor element; and
a connection element, electrically connecting the first semiconductor element and the second semiconductor element,
wherein the first semiconductor element comprises a first pad and a first dielectric layer surrounding the first pad, the connection element comprises a second pad and a second dielectric layer surrounding the second pad, the first pad is directly bonded to the second pad, and the first dielectric layer contacts the second dielectric layer,
wherein a material of one of the first dielectric layer and the second dielectric layer comprises silicon oxide, and a material of other one of the first dielectric layer and the second dielectric layer comprises silicon nitride.

18. The semiconductor device according to claim 17, further comprising:
a gap, disposed between a part of the first dielectric layer and a part of the second dielectric layer, wherein the gap is adjacent to the first pad or the second pad.

19. The semiconductor device according to claim 17, wherein a thickness of one of the first dielectric layer and the second dielectric layer is greater than a thickness of other one of the first dielectric layer and the second dielectric layer.

20. The semiconductor device according to claim 17, further comprising:
a circuit substrate, wherein the first semiconductor element further comprises a third pad, the circuit substrate comprises a fourth pad, and the third pad is bonded to the fourth pad through a conductive material.
